(19) United States
(12) Patent Application Publication
(10) Pub. No.: US 2012/0068268 A1
(43) Pub. Date: Mar. 22, 2012

(54) TRANSISTOR STRUCTURE AND METHOD OF FABRICATING THE SAME

(76) Inventors: Tsai-Fu Hsiao, Tainan City (TW); Tsuo-Wen Lu, Kaohsiung County (TW); Yu-Ren Wang, Tai-Nan City (TW)

(21) Appl. No.: 12/888,351

(22) Filed: Sep. 22, 2010

(51) Int. Cl. H01L 27/088; H01L 21/336

(52) U.S. Cl. 257/368; 438/294; 257/E27.06; 257/E21.409

(57) ABSTRACT

A method of fabricating a transistor structure includes the step of providing a substrate having a gate thereon. Then, a first spacer is formed at two sides of the gate. After that, an LDD region is formed in the substrate at two sides of the gate. Later, a second spacer comprising a carbon-containing spacer and a sacrificing spacer is formed on the first spacer. Subsequently, a source/drain region is formed in the substrate at two sides of the gate. Finally, the sacrificing spacer is removed entirely, and part of the carbon-containing spacer is also removed. The remaining carbon-containing spacer has an L shape. The carbon-containing spacer has a first carbon concentration, and the sacrificing spacer has a second carbon concentration. The first carbon concentration is greater than the second carbon concentration.

### BACKGROUND OF THE INVENTION

1. Field of the Invention

The invention relates to a transistor structure and a method of fabricating the same, and more particularly, to a transistor structure and a method of increasing the strain in the gate channel.

2. Description of the Prior Art

For decades, chip manufacturers have made metal-oxide-semiconductor (MOS) transistors faster by making them smaller. As semiconductor processes have advanced to the very deep sub-micron era, how to increase the driving current for MOS transistors has become a critical issue.

In order to improve device performance, crystal strain technology has been developed. Strained silicon transistors are becoming more and more attractive as a means for getting better performance in the field of transistor fabrication. Putting a strain on a semiconductor crystal makes transistors work better by enabling electrical charges, such as electrons, to pass more easily through the silicon lattice of the gate channel.

Strain in silicon can be induced in different ways: through stresses created by films in a form of poly stressor or contact etch stop layer (CESL) and structures that surround the transistor, called process-induced strain, or by employing a strained silicon wafer, where the top layer of silicon has typically been grown on top of a crystalline lattice that is larger than that of silicon. As known in the art, tensile stress improves electron mobility and compressive stress improves hole mobility.

Currently, as higher speeds of transistors are demanded, it is desirable to employ as high a stress as possible in the fabrication of transistors . Therefore, there is a need in this industry to provide a method of forming transistors with high stress for next-generation processes.

### SUMMARY OF THE INVENTION

It is one objective of the present invention to provide a method and a structure of forming a high strained-Si channel for transistors.

According to a preferred embodiment of the present invention, the steps of forming a transistor include providing a substrate with a gate thereon. Then, a first spacer is formed at least at two sides of the gate. Later, a lightly doped drain (LDD) region is formed in the substrate at one sides of the gate. A second spacer comprising a carbon-containing spacer and a sacrificing spacer thereon is then formed on the first spacer, wherein the carbon-containing spacer contacts the first spacer and the sacrificing spacer contacts the carbon-containing spacer. Subsequently, a source/drain region is formed in the substrate at one sides of the gate. Later, the entire sacrificing spacer, and part of the carbon-containing spacer are removed to make the profile of the carbon-containing spacer become an L shape. Finally, a silicide layer is formed on the source/drain region, wherein the silicide layer is closer to the gate than the source/drain region is.

According to another preferred embodiment of the present invention, a transistor structure includes: a substrate, and a transistor positioned on the substrate, wherein the transistor comprises: a gate positioned on the substrate, agate dielectric layer positioned between the substrate and the gate, a composite spacer positioned at least at two sides of the gate, wherein the outermost surface of the composite spacer has an L-shaped profile, a source/drain region positioned in the substrate at one side of the substrate and a silicide layer positioned on the source/drain region, wherein the silicide layer is closer to the gate than the source/drain region is.

The different carbon concentrations in the spacers lead to different etching rates of the spacers in a wet etching process. The spacer with higher carbon concentration remains, while the spacer with lower carbon concentration is removed after the wet etching process is completed. Since the spacer with lower carbon concentration is removed, the total width of the spacers is reduced. As a result, the stressor applied afterwards can provide higher stress to the gate channel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 5 depict a method of fabricating a transistor according to a preferred embodiment of the present invention.

FIG. 6 depicts a side view of a FinFET.

### DETAILED DESCRIPTION

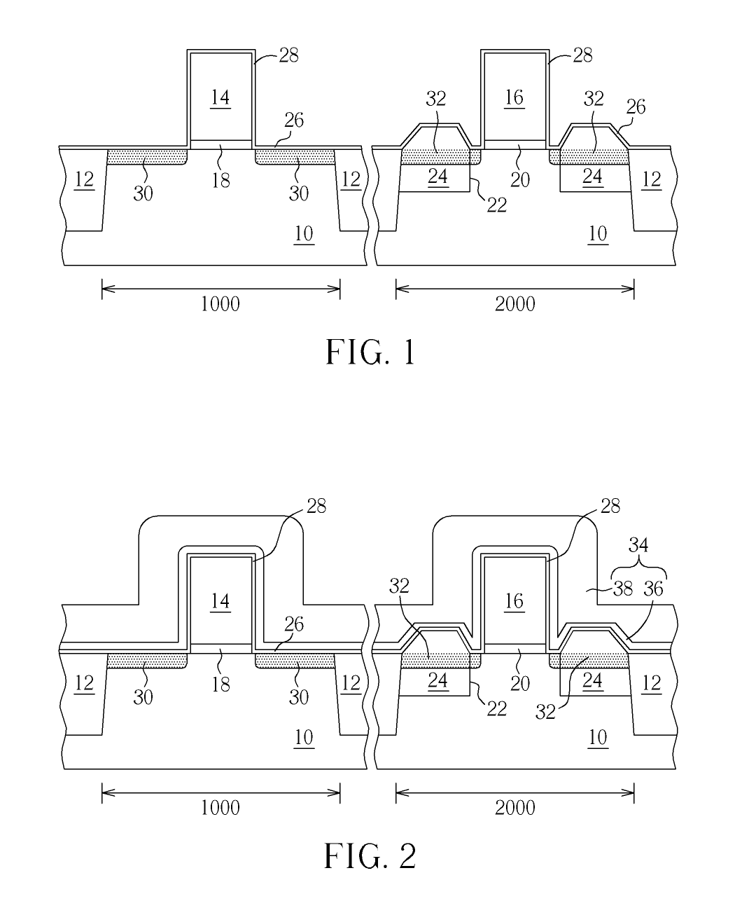

FIGS. 1 to 5 depict a method of fabricating a transistor according to a preferred embodiment of the present invention. FIG. 6 depicts a side view of a FinFET.

As shown in FIG. 1, a substrate 10 with a first transistor region 1000 and a second transistor region 2000 is provided. A shallow trench isolation 12 isolates the first transistor region 1000, and the second transistor region 2000. A first gate 14 and a second gate 16 are positioned on the substrate 10 within the first transistor region 1000 and the second transistor region 2000. A first gate dielectric layer 18 is disposed between the first gate 14 and substrate 10. A second gate dielectric layer 20 is disposed between the second gate 16 and the substrate 10. Then, two recesses 22 are formed in the substrate at two sides of the second gate 16. Later, an epitaxial layer 24 such as SiGe or SiC is formed in the recesses 22. A first spacer material layer 26 is then formed to cover the first gate 14, the second gate 16, the substrate 10 and the epitaxial layer 24 conformally. The first spacer material layer 26 at the sidewall of the first gate 14 and the second gate 16 is defined as a first spacer 28. Subsequently, lightly doped drain (LDD) regions 30, 32 are formed in the substrate 10 at two sides of the first gate 14 and the second gate 16 respectively, by taking the first spacer 28, the first gate 14 and the second gate 16 as a mask.

As shown in FIG. 2, a second spacer material layer 34 is formed conformally to cover the first spacer material layer 26. The second spacer material layer 34 can be formed by numerous material layers. For example, the second spacer material layer 34 can include a carbon-containing material layer 36 and a sacrificing material layer 38 to make a second spacer made of the carbon-containing material layer 36 and the sacrificing material layer 38 become a composite spacer. The structure of the second spacer will be shown in detail in the following fabrication steps. The formation of the carbon-containing material layer 36 maybe through an ion implantation method or an in-situ doping method. More specifically, the in-situ doping method can be performed by inputting carbon during the chemical vapor deposition method, so the carbon-containing material layer 36 can be formed. The carbon can be inputting with a flow rate of 100 to 1500 sccm. Preferably, the flow rate is 1200 sccm. The ion implantation method can be performed by forming a material layer, followed by implanting carbon into the material layer to form the carbon-containing material layer 36. The concentration of the carbon in the material layer is between 10E21 to 10E22 atm/cm³. After an etching step is performed, the carbon-containing material layer 36 will become a carbon-containing spacer. The carbon-containing material layer 36 is preferably carbon-containing silicon nitride. The carbon-containing material layer 36 preferably has a first carbon concentration between 10E21 to 10E22 atm/cm³.

Moreover, the sacrificing material layer 38 and the carbon-containing material layer 36 can be formed in the same chamber, wherein the sacrificing material layer 38 can be formed after the carbon-containing material layer 36 is formed. The sacrificing material layer 38 may optionally contain carbon, as long as a second carbon concentration of the sacrificing material layer 38 is lower than the first carbon concentration. Similarly, the sacrificing material layer 38 can be formed through an ion implantation method or an in-situ doping method. For example, the sacrificing material layer 38 can be formed by inputting carbon with a flow rate between 0 to 1500 sccm into the chamber. Preferably, the flow rate of carbon is 0 sccm. The sacrificing material layer 38 is preferably silicon nitride.

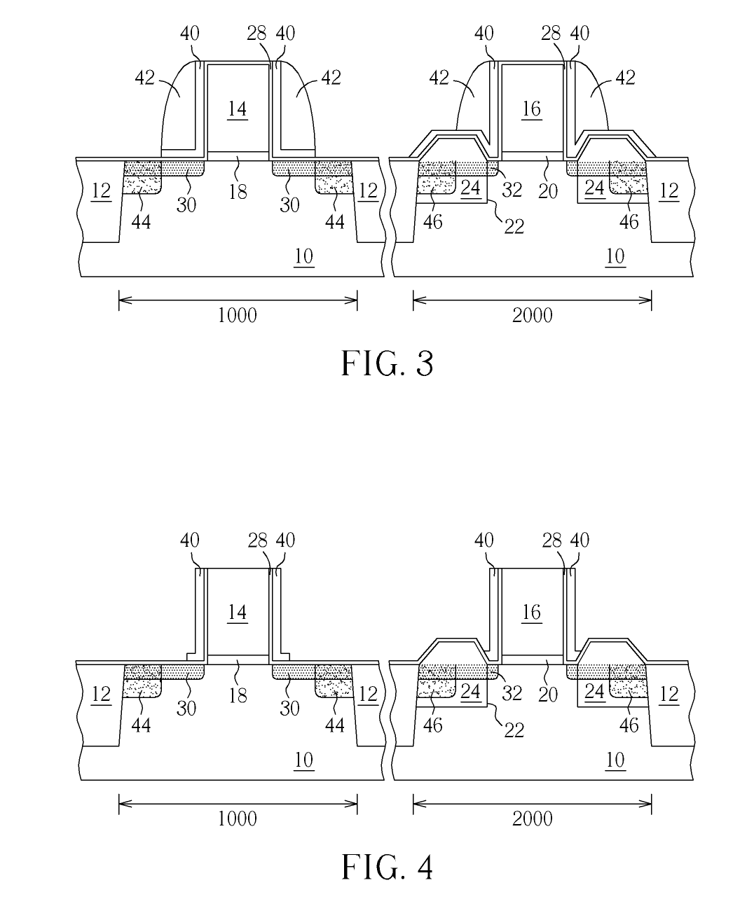

As shown in FIG. 3, the carbon-containing material layer 36 and the sacrificing material layer 38 are etched to form a carbon-containing spacer 40 and a sacrificing spacer 42. Because the carbon-containing spacer 40 and the sacrificing spacer 42 are formed by shaping the carbon-containing material layer 36 and the sacrificing material layer 38, the carbon-containing spacer 40 has the first carbon concentration and the sacrificing spacer 42 has the second carbon concentration. The first carbon concentration is greater than the second carbon concentration. According to a preferred embodiment of the present invention, the second carbon concentration is 0. That is, the sacrificing spacer 42 does not contain carbon. It is note-worthy that the first carbon concentration can be altered based on different product requirements. Moreover, the distribution of the first carbon concentration may be a fixed value. That is, the carbon concentration in every portion of the carbon-containing spacer 40 is the same. In another preferred embodiment, the distribution of the first carbon concentration may be varied. For example, a portion of the carbon-containing spacer 40 near the first gate 14 and the second gate 16 has a higher carbon concentration, and a portion of the carbon-containing spacer 40 far from the first gate 14 and the second gate 16 has a lower carbon concentration. Similarly, the distribution of the second carbon concentration maybe a fixed value or a varied value. If the second carbon concentration is a varied value, a portion of the sacrificing spacer 42 near the first gate 14 and the second gate 16 has a higher carbon concentration, and a portion of the sacrificing spacer 42 far from the first gate 14 and the second gate 16 has a lower carbon concentration.

After the carbon-containing spacer 40 and the sacrificing spacer 42 are completed, source/drain regions 44, 46 are formed in the substrate 10 at two sides of the first gate 14 and the second gate 16 respectively by taking the first gate 14, the second gate 16, the first spacer 28, the carbon-containing spacer 40 and the sacrificing spacer 42 as a mask.

As shown in FIG. 4, the sacrificing spacer 42 is removed entirely and the carbon-containing spacer 40 is removed partly by wet etching, for example, by using hot phosphoric acid. The hot phosphoric acid has different etching rates for materials with different carbon concentrations. If the material has a higher carbon concentration, the etching rate of the hot phosphoric acid to the material becomes slower. Therefore, the sacrificing spacer 42 will be etched faster than the carbon-containing spacer 40. As a result, most of the carbon-containing spacer 40 will remain on the gate and the carbon-containing spacer 40 will have an L shape. The sacrificing spacer 42, however, is removed entirely. According to another embodiment, the carbon concentration in the sacrificing spacer 42 can be increased to leave part of the sacrificing spacer 42 on the gate after the wet etching.

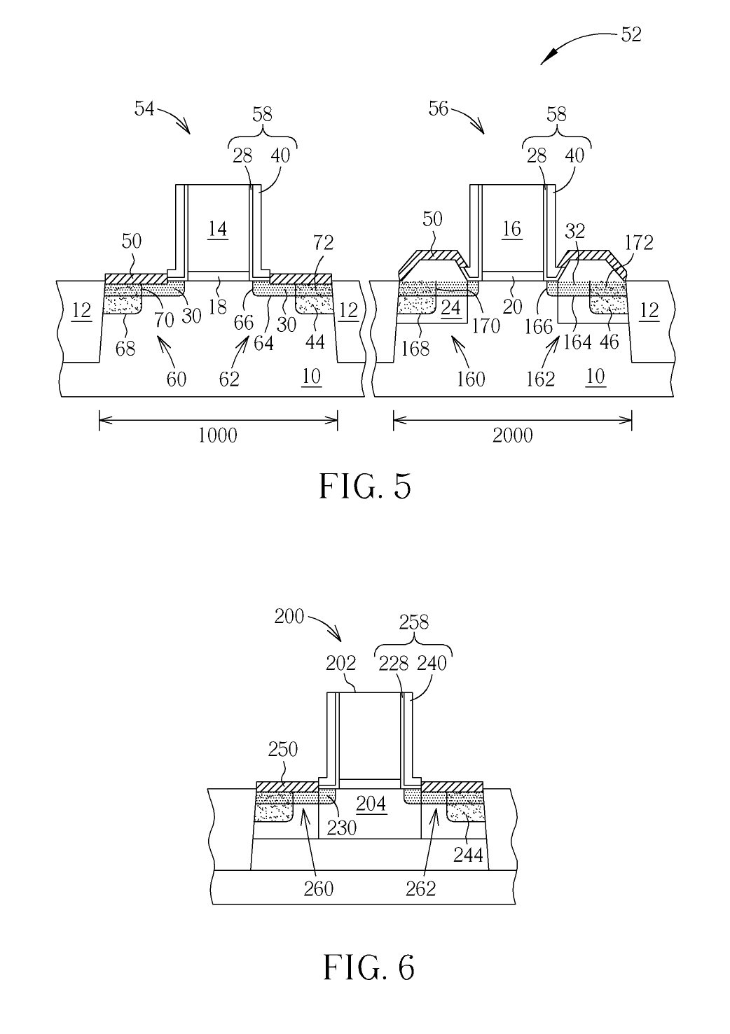

As shown in FIG. 5, a salicide process is performed to form a silicide layer 50 on the LDD regions 30, 32, and the source/drain regions 44, 46 respectively. The silicide layer 50 is closer to the first gate 14 than the source/drain regions 44 are. The silicide layer 50 is closer to the second gate 16 than the source/drain regions 46 are. At this point, the transistor structure 52 of the present invention is completed. After that, a stressor can be formed on the transistor structure 52 to form strained-Si channels under the first gate 14, and the second gate 16.

In another embodiment of the present invention, elements having the same function as in the above-described embodiment will be designated with the same numeral. As shown in FIG. 5, a first transistor 54 includes a substrate 10, and a first gate 14 disposed on the substrate 10. A first gate dielectric layer 18 disposed between the first gate 14 and the substrate 10. A composite spacer 58 is disposed at least at two side of the first gate 14, wherein the outmost surface of the composite spacer 58 has an L-shaped profile. Two source/drain regions 60, 62 are disposed in the substrate 10 at two sides of the first gate 14. A silicide layer 50 is disposed on the source/drain regions 60, 62. The composite spacer 58 includes a first spacer 28 and a carbon-containing spacer 40. The first spacer 28 contacts the first gate 14, and the carbon-containing spacer 40 contacts the first spacer 28. The outermost surface of the carbon-containing spacer 40 is the outermost surface of the composite spacer 58. Moreover, the carbon concentration of the carbon-containing spacer 40 is between 10E21 to 10E22 atm/cm³. The carbon-containing spacer 40 is preferably carbon-containing silicon nitride.

Furthermore, source/drain regions 60, 62 of the first transistor 54 include a LDD region 30 and a source/drain region 44 respectively. The LDD region 30 has a first bottom 64 and a first front 66. The source/drain region 44 has a second bottom 68 and a second front 70. The LDD region 30 is shallower than the source/drain region 44. In other words, a distance between the first bottom 64 and a surface of the substrate 10 is smaller than a distance between the second bottom 68 and the surface of the substrate 10. Part of the LDD region 30 overlaps part of the source/drain region 44 and forms an overlapping region 72. In addition, a distance between the first front 66 and the first gate 14 is smaller than a distance between the second front 70 and the first gate 14.

It is note-worthy that the silicide layer 50 covers the second front 50. More particularly, the silicide layer 50 covers the overlapping region 72 and a part of the LDD region 30 which does not overlap with the source/drain region 44. The silicide layer 50 is closer to the first gate 14 than the source/drain region 44 is.

In addition, the source/drain regions can further include an epitaxial layer respectively. As shown in FIG. 5, a second transistor 56 includes a substrate 10, and a second gate 16 disposed on the substrate 10. A second gate dielectric layer 20 is disposed between the second gate 16 and the substrate 10. A composite spacer 58 is disposed at least at two sides of the second gate 16, wherein the outermost surface of the composite spacer 58 has an L-shaped profile. Two source/drain regions 160, 162 are disposed in the substrate 10 at two sides of the second gate 16. A silicide layer 50 is disposed on the source/drain regions 160, 162. The composite spacer 58 includes a first spacer 28 and a carbon-containing spacer 40. The first spacer 28 contacts the second gate 16, and the carbon-containing spacer 40 contacts the first spacer 28. The outermost surface of the carbon-containing spacer 40 is the outermost surface of the composite spacer 58. Moreover, the carbon concentration of the carbon-containing spacer 40 is between 10E21 to 10E22 atm/cm³. The carbon-containing spacer 40 is preferably carbon-containing silicon nitride.

Furthermore, source/drain regions 160,162 of the second transistor 56 includes a LDD region 32 and a source/drain region 46 respectively. The LDD region 32 has a first bottom 164 and a first front 166. The source/drain region 46 has a second bottom 168 and a second front 170. The LDD region 32 is shallower than the source/drain region 46. Part of the LDD region 32 overlaps part of the source/drain region 46 and forms an overlapping region 172. In addition, the first front 166 is nearer the second gate 16 than the second front 170 is. The silicide layer 50 covers the overlapping region 172 and a part of the LDD region 32 which does not overlap with the source/drain region 46. In other words, the silicide layer 50 is closer to the second gate 16 than the source/drain region 46 is.

Moreover, based on different product requirements, the composite spacer 58 can merely at two side of the first gate 14 and the second gate 16. Alternatively, the composite spacer 58 can be disposed around the first gate 14 and the second gate 16.

The composite spacer can be also applicable to additional semiconductor devices, such as, but limited to, buried channel devices, MISFET, and non-planar devices such as FinFET and Tri-gate. For example, as shown in FIG. 6, a FinFET 200 includes a gate structure 202, a fin structure 204, source/drain regions 260, 262 disposed at two sides of the gate structure 202. Each of the source/drain regions 260, 262 includes an LDD region 230 and a source/drain region 244. A composite spacer 258 is disposed at at least two sides of the gate structure 200. The composite spacer 258 includes a carbon-containing spacer 240 and a first spacer 228. The fabricating method of the composite spacer 250 is omitted here, please refer to FIG. 1 through FIG. 4 for detail. Moreover, a silicide layer 250 is disposed on the source/drain regions 260, 262. The silicide layer 250 is closer to the gate structure 202 than the source/drain region 244 is.

The spacer 42 around the gates 14, 16 is intentionally removed partly after the source/drain regions 44, 46 are completed. Because the thickness of the spacer on the gates 14, 16 is reduced, the stressor disposed on the transistors 54, 56 can offer higher stress to the gate channel. Therefore, the performance of the transistors 54,56 is increased. Furthermore, because hot phosphoric acid has different etching rates for materials with different carbon concentrations, the final spacer 58 thickness can be controlled by adjusting the carbon concentration in the spacer. As a result, a spacer 58 with adequate thickness can be formed.

Those skilled in the art will readily observe that numerous modifications and alterations of the device and method may be made while retaining the teachings of the invention.

What is claimed is:

1. A method of fabricating a transistor, comprising:
providing a substrate with a gate thereon;
forming a carbon-containing spacer at least at two side of the gate;
forming a sacrificing spacer on the carbon-containing spacer;
forming a source/drain region in the substrate on two side of the gate;
removing the sacrificing spacer, and part of the carbon-containing spacer; and
forming a salicide layer one the source/drain region, wherein the salicide layer is closer to gate than the source/drain region is.

2. The method of fabricating a transistor of claim 1, wherein before the carbon-containing spacer is formed on the gate, further comprises:
forming a first spacer at two sides of the gate; and
forming a lightly doped drain (LDD) in the substrate at two side of the gate.

3. The method of fabricating a transistor of claim 2, wherein before the first spacer is formed, an epitaxial layer is formed in the substrate at two sides of the gate.

4. The method of fabricating a transistor of claim 1, wherein the carbon-containing has a first carbon concentration, and the sacrificing spacer has a second carbon concentration.

5. The method of fabricating a transistor of claim 4, wherein the first carbon concentration is greater than the second carbon concentration.

6. The method of fabricating a transistor of claim 4, wherein the second carbon concentration is 0.

7. The method of fabricating a transistor of claim 4, wherein the distribution of the second carbon concentration changes with the distance between the sacrificing spacer and the gate.

8. The method of fabricating a transistor of claim 1, wherein the carbon-containing spacer comprises carbon-containing comprises silicon nitride.

9. The method of fabricating a transistor of claim 1, wherein the carbon containing spacer is formed by an ion implantation method or an in-situ doping method.

10. The method of fabricating a transistor of claim 1, wherein the sacrificing spacer is removed by hot phosphoric acid.

11. The method of fabricating a transistor of claim 1, wherein the step of forming the carbon-containing spacer comprises inputting carbon with a flow rate of 100 to 1500 sccm into a chamber.

12. The method of fabricating a transistor of claim 1, wherein the step of forming the sacrificing spacer comprises inputting carbon with a flow rate of 0 to 1500 sccm into a chamber.

13. A transistor structure, comprising:
a substrate; and
a transistor positioned on the substrate, wherein the transistor comprises:
a gate positioned on the substrate;
a gate dielectric layer positioned between the substrate and the gate;
a composite spacer positioned at least at two sides of the gate;
a first source/drain region positioned in the substrate at two sides of the gate; and
a silicide layer positioned on the first source/drain region, wherein the silicide layer is closer to the gate than the first source/drain region is.

14. The transistor structure of claim 13, wherein the composite spacer comprises a first spacer contacting the gate and a second spacer contacting the first spacer.

15. The transistor structure of claim 14, wherein the second spacer comprises carbon-containing comprises silicon nitride.

16. The transistor structure of claim 13, further comprising an epitaxial layer positioned in the substrate at two sides of the gate, wherein the epitaxial layer partly overlaps the first source/drain region.

17. The transistor structure of claim 13, wherein the first source/drain region comprises a LDD region and a second source/drain region.

18. The transistor structure of claim 17, wherein the LDD region has a first bottom and a first front, and the second source/drain region has a second bottom and a second front.

19. The transistor structure of claim 18, wherein a first distance between the first bottom and a surface of the substrate is smaller than a second distance between the second bottom and the surface of the substrate.

20. The transistor structure of claim 19, wherein a third distance between the first front and the gate is smaller than a fourth distance between the second front and the gate.

21. The transistor structure of claim 20, wherein the silicide layer covers the second front.

22. The transistor structure of claim 17, wherein part of the LDD region overlaps part of the second source/drain region and form an overlapping region.

23. The transistor structure of claim 22, wherein the silicide covers the overlapping region and the LDD region which does not overlap with the second source/drain region.

24. The transistor structure of claim 13, wherein the composite spacer is disposed around the gate.
